(19) United States
(12) Patent Application Publication
(10) Pub. No.: US 2011/0134617 A1
(43) Pub. Date: Jun. 9, 2011

(54) POLYMER MOLDED BODIES AND PRINTED CIRCUIT BOARD ARRANGEMENT AND METHOD FOR THE PRODUCTION THEREOF

(75) Inventor: Peter Putsch, Rathsberg (DE)

(73) Assignee: PP-MID GMBH, Jena (DE)

(21) Appl. No.: 13/058,013

(22) PCT Filed: Aug. 7, 2009
(86) PCT No.: PCT/EP09/05757

§ 371 Date: Feb. 8, 2011

(30) Foreign Application Priority Data
Aug. 8, 2008 (EP) 08162124.5
Sep. 23, 2008 (DE) 10 2008 048 459.8
Dec. 8, 2008 (DE) 10 2008 061 051.8
Mar. 3, 2009 (DE) 10 2009 011 538.2

(51) Int. Cl. H05K 7/00; H05K 3/00; B32B 7/12; B32B 5/16; B32B 27/18; B82Y 99/00; B82Y 40/00; B82Y 30/00

(52) U.S. Cl. 361/760; 264/105; 427/98.5; 156/327; 428/206; 977/742; 977/842; 977/932

(57) ABSTRACT

The present invention relates to polymer moldings with conductive, especially electrically conductive, structures on the surface, and to a process for production of these polymer moldings. A further aspect of the invention relates to the use of a device for production of the conductive, especially of the electrically conductive, structures on the surface of the polymer molding. The invention additionally relates to the use of an adhesive comprising carbon nanotubes (CNTs) for electrically conductive bonding of an electronic component to another electrically conductive component or molding.

The invention additionally relates to a circuit board arrangement comprising at least one circuit board with at least one electrically conductive track. The at least one electrically conductive track preferably comprises a metal layer and/or at least one electronic component.

The invention also relates to processes for production of the inventive circuit board arrangements.

The present invention relates to polymer moldings with conductive, especially electrically conductive, structures on the surface, and to a process for production of these polymer moldings. A further aspect of the invention relates to the use of a device for production of the conductive, especially of the electrically conductive, structures on the surface of the polymer molding. The invention additionally relates to the use of an adhesive comprising carbon nanotubes (CNTs) for electrically conductive bonding of an electronic component to another electrically conductive component or molding.

The invention additionally relates to a circuit board arrangement comprising at least one circuit board with at least one electrically conductive track. The at least one electrically conductive track preferably comprises a metal layer and/or at least one electronic component.

The invention also relates to processes for production of the inventive circuit board arrangements.

Electrically conductive polymers have long been known. U.S. Pat. No. 4,404,125 describes the production of such polymers by addition of carbon fibers, optionally together with conductive blacks, to a thermoplastic polymer. In U.S. Pat. No. 4,664,971, electrically conductive metal fibers are used in place of the carbon fibers. In all these polymer mixtures, large amounts of electrically conductive additives are required, which are generally within a range of 10-30% by weight. Nevertheless, the electrical conductivity of these polymers, especially at the surface, is still insufficient for many industrial applications.

WO 02/19346 describes the use of metal-coated carbon fibers for production of electrically conductive polymers. This involves using, for example, a high-energy laser to vaporize the polymer present at the surface and to expose the underlying layers of the electrically conductive additives. One disadvantage in this case is the frequent occurrence of conductivity over the entire volume of the polymer, including transverse to and beyond the laser-treated track, and the resulting problems in the arrangement of conductor tracks alongside one another.

In order to achieve a good electrical conductivity, sufficient amounts of additives are required in all these processes, and the conductivity is distributed substantially homogeneously over the volume of the polymer molding. The rise in filler level is, however, generally associated with a deterioration in the mechanical properties, and so, for example, toughness, and also tensile strength and breaking strength, are distinctly reduced at high filler levels.

A further means for production of electrically conductive structures on surfaces has been described by T. Dekker (Carbon-Nanotubes as Molecular Quantum Wires, Physics Today, p. 22-28, 1999). This involves depositing carbon nanotubes from the gas phase on a substrate. This process is likewise associated with a high level of technical complexity.

US 2006/0062983 A1 discloses a process in which a CNT-containing polymer film is applied to a substrate. The CNT-containing polymer film is conductive.

WO 2007/114645 discloses a process for applying a CNT-containing polymer layer to a substrate, using an aqueous dispersion which comprises CNTs.

Electronic circuits are generally produced by applying a copper layer to a substrate, the parts of the copper layer not required for the circuit being etched away by chemical processes. The production of such circuits is generally very complex and comprises many process steps.

In the production of conductive structures, it is possible to use the electroplating process in particular. In order to be able to use this process for polymer surfaces too, it is first necessary to apply a conductive layer on the polymer surface, before a metallic layer can be deposited by an electroplating method. Processes suitable for this purpose are known and comprise several individual treatment steps, which are inconvenient and laborious. It would therefore be advantageous if it were possible to directly electroplate the polymer surfaces.

One variant of polymer components which can be produced using the electroplating process is that of molded interconnect devices (MIDs). In the case of these injection-molded components, metallic conductor tracks are applied to polymer carriers. These MIDs can be produced in different ways. One option is to produce the circuit carrier in a two-component injection molding operation. One polymer here forms the base body; a further polymer is metalizable and forms the conductor track layout. In the SKW process, the conductor track structure is first injection-molded as a depression from the non-metalizable component. Subsequently, these regions are filled with the metalizable components. In the subsequent steps, the corresponding metals are applied to the metalizable polymer. In this case, the surface of the metalizable polymer is first activated. Copper is applied to this surface by electroplating up to the desired thickness.

A further problem in industry is presented by the securing of the electronic components on the circuit boards. In this case, the components have to be secured in a simple manner such that outstanding or optimal electrical properties can be achieved. Adhesives suitable for this purpose are known, for example, from EP 0 914 027 or EP 0 870 418. In order to obtain an electrically conductive bond between the conductor tracks and the electronic components, electrically conductive substances are added here to the polymers. However, these adhesive bonds often do not attain the desired conductivity and strength, and there is especially a need for novel adhesive compositions and/or bonds which interact outstandingly or optimally with the properties of the circuit boards.

It is therefore an object of the present invention to provide circuit board arrangements wherein the circuit boards comprise or constitute inventive polymer moldings with conductive, especially electrically conductive, structures on the surface, and the conductive structures optionally comprise metals, preferably copper. In addition, a simple process is to be provided for bonding electronic (or other) components to the circuit boards.

In a first aspect, the invention therefore relates to a polymer molding with conductive, especially electrically conductive, structures on the surface, and to a process for producing these polymer moldings.

It was a further object of the present invention to simplify and to improve the known processes for production of conductive structures on polymer moldings, and more particularly to provide polymer moldings with particularly good properties.

This object is achieved by the polymer moldings defined herein and the process for production thereof.

In the context of the present invention, it has been found that, surprisingly, the partial melting of the surface of a polymer molding which comprises carbon nanotubes leads to migration of the CNTs to the surface of the polymer molding. It is thus possible in an advantageous manner, by controlled melting of the surface in defined regions, to increase the concentration of the CNTs in these regions and to increase the electrical and thermal conductivity of these regions. Consequently, the concentration of the CNTs in the untreated, i.e. unmelted, regions of the surface (which likewise comprise CNTs) is unchanged or virtually unchanged. Thus, the untreated, nonconductive surface regions have the original concentration of CNTs. This is therefore non-zero. In contrast, the application (for example by printing) of conductive structures of CNT-containing polymer material onto a nonconductive surface (of a material which does not contain CNTs) leads to different (non-inventive) polymer moldings. These have a high CNT concentration in the conductive regions, but no CNTs in the nonconductive regions. The process according to the invention therefore differs fundamentally from a process in which conductive structures are obtained by applying material to surfaces.

Instead, the result of the process according to the invention is that a nonconductive surface is treated such that defined regions become conductive, and the remaining, untreated regions remain unchanged or virtually unchanged (nonconductive).

Evidence for the higher concentration of the CNTs in the electrically conductive (thermally treated) regions can be provided, for example, by means of light micrographs or electron micrographs. In these, for example, in the case of a polymer molding composed of polycarbonate and CNT, the sites with high CNT density appear black in the light microscope, whereas the sites with low but (preferably) non-zero CNT density are white.

In contrast, it has been found, surprisingly, in the context of the present invention, that the use of polymer moldings with different electrically conductive additives does not lead to migration of the conductive substances to the surface. For example, the melting of polymer moldings comprising conductive fiber systems, for example Aluflakes (manufacturer: Aluflakes from Silverline, GB; polymer mixture used: polycarbonate/polypropylene; see example) or steel fibers, did not lead to migration of the conductive fibers to the surface. In the case of these polymer moldings, therefore, only the above-described process from WO 02/19346 can be employed. In the process according to the invention, however, advantageously no vaporization of the polymer on the surface of the polymer molding is necessary.

In the process according to the invention, the rate of migration depends both on the viscosity of the polymer phases through which the CNTs have to move and on the particular compatibility of the surfaces of the CNTs and of the polymer phases, and on the treatment time, i.e. on the time available for the CNTs to penetrate through the molten polymer to the surface. The longer the duration of the melting, the better the CNTs can migrate to the surface, and the better also the increase in electrical conductivity in the thermally treated regions.

In addition, it has been found that, surprisingly, stretching or bending of the polymer molding alters the surface resistance thereof. More particularly, the more the polymer molding is stretched, the greater the surface resistance becomes. This enables the use of the inventive polymer moldings in strain gauges.

The present invention therefore relates, in one aspect, to polymer moldings with conductive, especially electrically conductive, structures on the surface, and to a process for producing these polymer moldings.

A polymer molding in the context of the present invention is a three-dimensional body of any shape or a polymer layer composed of one or more different polymers, which are described hereinafter both for the process according to the invention and for the inventive polymer moldings.

Polymers suitable in accordance with the invention are thermoplastics, thermosets, elastomers and inorganic polymers and mixtures thereof, preference being given to using thermoplastics and thermosets.

Preferably in accordance with the invention, the polymer molding comprises polyolefins, for example in an addition of at least 1% by weight, preferably at least 10% by weight, for example between 10 and 100% by weight, additionally, for example, between 10 and 50% by weight, based on the weight of the polymer molding or of the polymer phase. More preferably, the polymer molding consists of polyolefins, in one embodiment of cyclic polyolefins. Preferred polyolefins which can be used in accordance with the invention include cyclic polyolefins and copolymers thereof. Preference is given to using cyclic polyolefins or copolymers thereof in combination with polypropylene, preferably linear polypropylene. In an advantageous embodiment, about 10 to 50% by weight of cyclic polyolefins are used as an addition, based on the overall polymer phase. Cyclic polyolefins are based on cyclic olefin monomers or mixtures of cyclic and linear olefin monomers. Particularly suitable examples are cyclic polyolefins with the Topas® trade name, for example Topas® (COC) 6015 (commercially available from Topas Advanced Polymers GmbH, Germany). Particular preference is given to cyclic polyolefins based on ethylene and norbornene or norbornene derivatives.

It has been found that the use of cyclic polyolefins and copolymers thereof, together with or instead of linear polypropylene, leads to an increase in the thermal stability of the polymer moldings, which is advantageous especially in the case of use of the materials close to the heat source (for example in the engine compartment).

Additionally preferably, the Vicat softening temperature of the polymers used in accordance with the invention is between 80° C. and 250° C., preferably between 100° C. and 250° C., more preferably between 110° C. and 250° C., even more preferably between 130° C. and 230° C. (measured to DIN EN ISO 306, 5 kg). In the context of the invention, in the case of use of Topas® (COC) 6015, a value of 150° C. was obtained, whereas the use of polypropylene led to a value of 110° C. The high Vicat softening temperature preferred in accordance with the invention is very advantageous especially for applications requiring elevated thermal stability (e.g. engine compartment, etc.).

Preferred polymers which can be used in a mixture with (or else instead of) polyolefins are polycarbonate, acrylonitrile-butadiene-styrene (ABS), polyamides such as nylon-6 (PA 6), nylon-6,6 (PA 66), nylon-6,4 (PA 64), nylon-12 (PA 12), aromatic polyamide, polyvinyl chloride, nylon-6,6, polyvinyl fluoride, polyvinylidene fluoride, polyphenylene ether, polystyrene, polyolefins such as polypropylene or polyethylene, polysulfone, thermoplastic polyurethane, polyethylene terephthalate, polybutylene terephthalate, thermoplastic elastomer alloys, acetal, styrene-maleic anhydride, butadiene-styrene, polyether ether ketone, polyether sulfone, polytetrafluoroethene, polyalkyl acrylates, polymethyl methacrylate, unsaturated polyesters, polylactones, polyepoxides, polyimines, polybutadienes, polyphosphazenes, styrene-maleic anhydride (SMA), styrene-methyl methacrylate (SMMA), polysulfone, polyvinyl acetate and polyacrylamide. In addition, it is possible to use phenol resin, polyester resin, natural or synthetic rubber or silicone rubber. Specific examples of inorganic polymers include phosphorus-based compounds and silicones. The polymers listed above can be prepared and processed in a manner known to those skilled in the art. Preference is given to using at least two, further preference to using at least three, different polymers to produce the polymer molding.

Preferred polymer blends are: polycarbonate/polyolefin (especially polypropylene or polyethylene), polyethylene terephthalate (PET)/polyvinylidene fluoride, PET/nylon-6,6, PET/polypropylene, PET/polyethylene mixtures with high density, nylon-6 (PA 6)/acrylonitrile-butadiene-styrene and polycarbonate/polyolefins (preferably polypropylene), nylon-(PA 6)/nylon-12 (PA 12), nylon-6,6 (PA 66)/nylon-12 (PA 12), aromatic polyamide/nylon-12 (PA 12), polybutylene terephthalate/thermoplastic polyester, and polyethylene terephthalate/thermoplastic polyester. Suitable polymer blends have been described, for example, by Wu et al. (Journal of applied polymer science, 2006, vol. 99, No. 2, pp. 477-488) in connection with CNTs. In the case of use of a plurality of different polymers, according to the nature of the polymers, a monophasic or polyphasic system may arise.

The polymers used in accordance with the invention preferably have a melting temperature within a range from 100° C. to 350° C., more preferably within a range from 150° C. to 350° C., more preferably within a range from 170° C. to 300° C., even more preferably within a range from 190° C. to 300° C.

Additionally preferably, the polymers used in accordance with the invention have a viscosity number between 0.1 ml/g and 300 ml/g, preferably between 100 ml/g and 300 ml/g, more preferably between 150 ml/g and 300 ml/g (determination of the viscosity number: decalin, 135° C., DIN 53 728).

Without being bound to a theory, it is assumed that a relatively low viscosity number is advantageous in the thermal treatment of the polymer molding for production of conductive structures, since the CNTs can alter their position more easily in the case of a lower viscosity of the polymer melt.

Additionally preferably, the CNT-containing polymer phase comprises additives, preferably adhesion promoters or compatibilizers. Adhesion promoters or compatibilizers are used to promote adhesive bonding between materials with, for example, different polarities. A “compatibilizer” is preferably a thermoplastic polymer which bonds two different thermoplastics to one another by a reactive or chemical (covalent, dipole-dipole, ionic or acid-base) bond, or by a non-reactive (chain-compatibilizing) agent. Examples are maleic anhydride-grafted polymers or ethylene-vinyl acetate-grafted polymers, for instance the product lines PLEXAR® from Quantum Chemical, ADMER® from Mitsui Petrochemical and BYNEL® from DuPont, ethylene-methyl acrylate and ionomers.

Additionally preferred assistants which can be used for the polymer molding are reinforcers such as glass fibers, glass beads or glass flakes, and minerals, for example talc, mica, wollastonite, kaolin, silicates or silicatic materials, including sheet silicates, preferably in amounts between 1 and 50% by weight, especially between 10 and 50% by weight.

Additionally preferably, the polymer molding may also comprise flame retardants, for example halogenated, phosphorus-containing, magnesium/aluminum-containing flame retardants, in amounts of preferably 1-60% by weight, especially about 10 to 60% by weight.

Additionally preferably, the polymer molding comprises at least one blowing agent, for example the blowing agent sold by Clariant under the “Hydrocerol” trade name. Further examples of blowing agents are azodicarbonamides (and modified variants of azodicarbonamides), sodium hydrogen carbonate, and sulfohydrazides, especially 4,4′-oxybis(benzenesulfonyl hydrazides), 5-phenyltetrazoles, p-toluenesulfonyl semicarbazides or p-toluenesulfonyl hydrazides. According to the invention, the blowing agent is introduced here before the shaping of the polymer molding, for example in the course of addition of the CNTs to the polymer. Customary amounts are used, for example within the range from about 0.1 to about 4% by weight. It is preferred that the blowing agent has a decomposition temperature which is above the processing temperature of the polymer or of the polymer mixture (in the case of production of the polymer molding, i.e. before the inventive thermal treatment of the polymer molding). The decomposition temperature of the blowing agent is therefore preferably above about 150° C., more preferably above 200° C. (for example in the case of azodicarbonamide, 5-phenyltetrazole and p-toluenesulfonyl semicarbazide). According to the desired polymers, the blowing agent in the polymer molding can be selected correspondingly such that the decomposition temperature thereof is above the processing temperature of the particular desired polymers. In addition, it is also preferred that the polymer/the polymer mixture has a low melting temperature or low processing temperature.

In the course of performance of the process according to the invention, especially by heat or laser treatment, the polymer molding is heated at defined sites above the decomposition temperature of the blowing agents. This creates cavities, or results in foaming of the polymer molding in the region of the conductive structures. This gives rise to raised conductive structures which surprisingly additionally still have an improved conductivity compared to structures which have been produced without using blowing agents. It is assumed here that the CNTs, as a result of the blowing agent or the decomposition thereof, assume a more favorable arrangement which promotes better conductivity. The present invention thus additionally relates to the use of blowing agents in polymers or polymer moldings, which are heated to produce defined (conductive) structures.

The polymer phase or the polymer molding preferably comprises at least one light-conducting additive and/or at least one heat-conducting additive with a conductivity of more than 20 W/mK. The at least one light-conducting additive and/or the at least one heat-conducting additive may preferably each be present at least 0.05% by weight, more preferably at least 0.1% by weight, more preferably at least 0.5% by weight, based on the total weight of the polymer molding or of the polymer phase. The amount used is preferably not more than about 70% by weight, especially not more than about 50% by weight, more preferably not more than about 10% by weight, more preferably not more than about 5% by weight, based on the total weight of the polymer molding or of the polymer phase. The use of these materials promotes the penetration of light/heat into deeper layers of the polymer phase during the inventive treatment, and hence leads to an improvement in the melting operation, and thus to an increase in the conductivity due to an elevated CNT concentration in the resulting structure. Light-conducting additives preferred in accordance with the invention are shaped glass bodies, which can be introduced, for example, in the form of glass fibers, beads or flakes. Suitable heat-conducting minerals are, for example, SiO₂ and silicates. Especially preferred are SiO₂ and silicates, since they are both light- and heat-conductive. Further materials are known to those skilled in the art, and the thermal conductivity of these materials can be determined by standard methods. It has been found that, especially in the case of use of a laser in the process according to the invention, the introduction of light- or heat-conducting additives leads to an improved conductivity of the structures produced. Suitable shaped glass bodies have, for example, a size (maximum dimension in a direction) of up to 50 μm, preferably up to 10 μm and most preferably up to 1 μm. The shaped glass bodies can, like the blowing agents too, be introduced into the still-liquid polymer phase before the shaping of the polymer molding, for example during the addition of the CNTs.

According to the invention, the polymer molding consists preferably of at least two essentially mutually immiscible (phase-incompatible) polymers. When two or more phase-incompatible polymers are used, they may themselves form a biphasic or polyphasic system after partial melting of the polymer molding. Phase-incompatible systems are known to those skilled in the art. When the two polymer types are mixed, they are present alongside one another in separate phases. When such a mixture is kept in the melt over a prolonged period, the domains formed from one polymer type each coalesce, i.e. phase separation takes place.

For example, polymers selected from the group consisting of polystyrene (PS), polymethyl methacrylate (PMMA) and acrylonitrile-butadiene-styrene (ABS), and also thermoplastic polyesters such as polyethylene terephthalate (PET) or polybutylene terephthalate (PBT), and polycarbonates are immiscible with polypropylene and/or polypropylene copolymers. In addition, polystyrene and nylon-6 are immiscible with polyethylene or polypropylene. Combinations of two or more of the aforementioned polymers are preferred in accordance with the invention, and the use of polycarbonate in combination with polypropylene is particularly preferred.

In the case of use of polypropylene and/or a polypropylene copolymer in a mixture with polymers phase-incompatible therewith, preference is given to using, based in each case on the total mass of the polymer mixture (including any assistants and carbon nanotubes used), at least 40% by weight, more preferably at least 60% by weight, even more preferably at least 80% by weight, more preferably at least 90% by weight and most preferably at least 99% by weight of polypropylene and/or polypropylene copolymer. Further preferred ranges are: 40 to 99% by weight, more preferably 60 to 95% by weight, even more preferably 70 to 95% by weight, of polypropylene and/or polypropylene copolymer.

Carbon nanotubes (CNTs) are fibrous structures formed from carbon atoms in a particular molecular arrangement. CNTs consist of wall sections which enclose cavities. The walls here are formed from carbon atoms having three bonding partners each, which form a honeycomb structure composed of hexagons. According to the arrangement of the wall structures, reference is made to single-wall carbon nanotubes (SWCNTs), which are formed from individual tubes and have an internal diameter of 1-3 nm, or to multiwall carbon nanotubes (MWCNTs), which consist of a plurality of concentric tubes. The external diameter of the carbon nanotubes is between 1 nm and 400 nm, and carbon nanotubes with an external diameter between 10 and 400 nm are frequently referred to as carbon nanofibers (CNFs).

The production of carbon nanotubes is known to those skilled in the art and can be effected, for example, in the light arc process (Iijima, Nature 354, 1991, 56-8) or by means of deposition processes from the gas phase (Chemical Vapor Deposition, CVD) (P. M. Ajayan, Nanotubes from Carbon, Chem. Rev. 99, p. 1787-1799, 1999). A further process is described in WO 99/13127, DE 19946182 and WO 98/39250. In this case, pulsed lasers serve to evaporate carbonaceous materials arranged in a vacuum chamber. Some of the carbon molecules evaporated condense on collectors, the temperature of which is controlled by external heating and cooling, which causes the growth of nanotubes. Further production methods include, for example, light arc processes, laser ablation processes and catalytic processes. WO 86/03455 and WO 2006/050903 describe production processes in which aliphatic or aromatic hydrocarbons are decomposed in the presence of an iron-containing catalyst at temperatures of 800-900° C. In the known processes, carbon black, amorphous carbon and fibers with high diameters are often formed as by-products. In the catalytic deposition of carbon from gaseous hydrocarbons (catalytic carbon vapor deposition), it is possible, for example, to use acetylene, methane, ethane, ethylene, butane, butene, butadiene or benzene. The catalysts used may, for example, be metals such as Fe or Ni, or else metal oxides. The carbon nanotubes produced using the above processes are usually obtained in the form of CNT powders and can be mixed directly with the polymers.

According to the invention, preference is given to using CNTs with a mean diameter of 2 to 100 nm, more preferably 5 to 80 nm and especially preferably 6 to 50 nm. Preference is given to using MWCNTs. The person skilled in the art is additionally aware that the carbon nanotubes, according to the symmetry or arrangement of the carbon hexagons in the tube walls, have different electronic states and can thus have properties of metals or semiconductors. According to the application, the person skilled in the art will therefore be able to select the suitable carbon nanotubes described in the literature.

According to the invention, it is also possible to use functionalized carbon nanotubes, provided that these carbon nanotubes do not bond to the polymers such that migration is prevented. Functionalized carbon nanotubes have a modified surface and are described, for example, in U.S. Pat. No. 6,203,814 and U.S. Ser. No. 08/812,856.

Instead of or in addition to the carbon nanotubes, in one possible embodiment of the invention, it is also possible to use graphenes instead of the CNTs or together with them. Graphenes and processes for production thereof are known to those skilled in the art. Graphenes are monoatomic graphite layers which can be produced, for example, by epitactic growth on a silicon oxide substrate. CNTs, however, are preferred in accordance with the invention.

Preferably in accordance with the invention, carbon nanotubes are used in such a proportion (based on the total mass of the polymer phase(s) of the polymer molding) that the polymer molding has zero or only low conductivity without the inventive conductive structures. In the case of pure polycarbonate materials, it is therefore possible, for example, to use a total only of less than about 5% by weight of CNTs. For polypropylene, it is possible to use a maximum of about 8-10% by weight of CNTs. A person skilled in the art will determine the suitable total amount of CNTs by tests according to the use of the inventive polymer molding.

Additionally preferably, it is possible to use nanocomposites in the process according to the invention or in the inventive polymer moldings. Such substances and the use thereof are known to those skilled in the art and are described, for example, in EP 1 776 418. Preference is given here to using nano sheet silicates, for example aluminum sheet silicate. Preference is given to using nanocomposites in a proportion, based on the total mass of the polymer phase(s) in the polymer molding, of 0.1 to 10% by weight, preferably of 0.5 to 5% by weight, especially preferably of 0.5 to 2% by weight.

Additionally preferably, the polymer phase(s) of the polymer molding may comprise further substances which can increase the electrical conductivity of the polymer molding. For example, metal-coated carbon fibers or the like may be present.

Additionally preferably, the polymer molding comprises, apart from polymeric constituents, CNTs and nanocomposites, a maximum of 20% by weight, more preferably a maximum of 10% by weight, of further substances such as processing aids, dispersing aids, adhesion promoters and compatibilizers, light and aging stabilizers, dyes, etc.

The expression “electrically conductive” as used here refers to a body having a surface resistance of less than 10⁹ ohms, preferably less than 10⁷ ohms, more preferably less than 10⁵ ohms and more preferably less than 10⁴ ohms. Accordingly, the expressions “electrically nonconductive” and “with low electrical conductivity” as used here relate to a body having a surface resistance of more than 10⁹ ohms, preferably more than 10⁷ ohms, more preferably more than 10⁵ ohms and especially preferably more than 10⁴ ohms. By virtue of the process according to the invention, it is possible to reduce the surface resistance in defined regions by a factor of 10, especially 100, especially 1000 or more, to produce electrically conductive structures.

An electrically conductive structure in the context of the present invention is a geometric arrangement of electrically conductive regions on the surface of a polymer molding, the electrically conductive regions adjoining electrically nonconductive regions on the surface. As described above, the nonconductive regions likewise consist of polymeric constituents comprising CNTs. More particularly, the electrically conductive structures may be configured for electronic applications. The electrically conductive structures may therefore have any desired geometric shapes, especially the shape of lines, areas or patterns, preferably always delimited by untreated (and hence electrically nonconductive) regions. In contrast to known conductive structures composed of CNT-containing materials, preferably in accordance with the invention, a CNT-containing layer is converted so as to give rise to conductive and nonconductive regions. However, conductive regions are not simply applied to a surface. Equally, conductive regions are not removed from the surface (for example by vaporization), such that only conductive structures remain. Thus, the process according to the invention is suitable for converting the surface of the CNT-containing polymer phase to conductive structures in a controlled manner. The process according to the invention can be performed much more easily than the known processes (for example than the process from US 2006/0062983) and enables the formation of smaller structures. In addition, the process according to the invention, due to the concentration of the CNTs at the surface, leads to a higher conductivity than that of the polymer layers which have the same CNT concentration as the inventive polymer phase and are applied to a substrate by known processes.

In addition to the electrical conductivity, the thermal conductivity of the thermally treated regions of the surface of the polymer molding also increases. This enables further possible industrial uses.

In a first step, the process according to the invention comprises the provision of a polymer molding composed of at least one polymer phase which comprises carbon nanotubes (CNTs).

This involves mixing one or more of the polymers listed above with the carbon nanotubes, while melting the polymers. The individual constituents can be mixed in any desired manner in principle. Known processes for producing polymers comprising CNTs involve melting the synthetic polymer, which is regularly in the form of granules or powder or else in block form, by supplying heat, and thus converting it to a liquid-viscous state. This allows the viscosity of the polymer to be lowered, and the CNTs to be mixed into the polymer. Such a process can be found in U.S. Pat. No. 4,157,325. Canadian published specification CA 2,324,353 A1 discloses mixing fillers into a monomer, starting an in situ polymerization and then melting the thermoplastic thus synthesized, in order to introduce further fillers therein. In this case, the carbon nanotubes can be added before or during the melting operation.

To mix substances into low-viscosity polymer precursors, it is possible, for example, to use the known dispersing processes using a bead mill, ultrasound probe, a three-roller mill or a high-pressure disperser. The known processes are used for mixing into high-viscosity polymer melts, for example the use of corotatory twin-screw extruders, for example from Coperion (Germany) or Leistritz (Germany), of counter-rotatory twin-screw extruders from Pomini (Italy) and Farell (USA), or the co-kneaders produced by Buss (Switzerland).

These processes can also be used when phase-incompatible polymers are used. For example, it is possible in this way to mix polypropylene and/or polypropylene copolymer with phase-incompatible polymers, and then to melt and combine them together. In the case of use of nanocomposites, it is likewise possible to add these before or during the melting.

Preferably, the polymer phase(s) is/are produced by mixing molten polymer with 0.1-10% by weight of carbon nanotubes, based on the total mass of the polymer phase(s) of the polymer molding.

In addition, it is possible to perform the mixing of all constituents in a plurality of successive steps. For example, it is possible first to mix a polymer with the carbon nanotubes while melting, and to mix and melt the masterbatch thus obtained with the remaining polymers in a subsequent step, for example after cooling and pelletization. The production of such masterbatches is described, for example, in U.S. Pat. No. 5,643,502. The use of such masterbatches allows the distribution of the carbon nanotubes in the polymer material to be improved.

It is additionally preferred here that the polymer molding is obtained by melting at least one polymer phase which comprises carbon nanotubes (CNTs) in a proportion (based on the polymer phase) between 1 and 40% by weight, more preferably between 5 and 30% by weight, more preferably between 15 and 30% by weight, with at least one further polymer phase with a lower carbon nanotube (CNT) content. In this case, the total content of CNTs should nevertheless not be so high that the polymer molding is conductive even without the inventive conductive structures. The polymer phases with different carbon nanotube (CNT) contents may in this case, as described above, be obtained by melting the polymers or polymer mixtures with the carbon nanotubes.

More preferably, the polymer phase with the higher carbon nanotube content is used in lower proportions by weight than the polymer phases with lower carbon nanotube contents. The polymer phases with lower carbon nanotube contents preferably comprise between 0 and 10% by weight of CNTs (based on the polymer phase), more preferably between 0 and 5% by weight of CNTs. The polymer phase with the higher carbon nanotube content will preferably be present in a proportion between 0.5 and 40% by weight, more preferably between 1 and 40% by weight, more preferably between 1 and 30% by weight, more preferably between 1 and 20% by weight and most preferably between 1 and 10% by weight, based on the total mass of the polymer phases of the polymer molding.

It has been found that, surprisingly, the use of two phase-incompatible polymer phases, one of which has a high carbon nanotube content, enables particularly high conductivity of the structures produced. It has been found here that the polymer phases, even after melting (in the course of production of the polymer molding), still have different carbon nanotube contents. In contrast, the known use of masterbatches with an elevated carbon black content, for example in processes for coloring polymer moldings, leads to homogeneous distribution of the carbon black particles between the polymer phases.

More preferably, the polymer phase which comprises carbon nanotubes (CNTs) in a higher proportion is produced here from one or more polymers selected from the group consisting of polycarbonate, polystyrene, acrylonitrile-butadiene-styrene (ABS), styrene-maleic anhydride (SMA), styrene-methyl methacrylate (SMMA), polymethyl methacrylate (PMMA), polybutylene terephthalate (PBT), polyethylene terephthalate (PET), nylon-6 (PA 6), nylon-6,6 (PA 66), nylon-6,4 (PA 64), nylon-12 (PA 12), aromatic polyamide, polysulfone. This polymer phase preferably consists to an extent of at least 50% by weight, more preferably to an extent of at least 60% by weight, more preferably to an extent of at least 70% by weight, even more preferably to an extent of at least 80% by weight and most preferably to an extent of at least 90% by weight of polycarbonate.

The desired polymer moldings can then be obtained in a customary manner by extrusion or injection molding processes from the polymer mixtures.

In a second step of the process according to the invention, thermal treatment of at least one surface of the polymer molding produces the conductive, especially the electrically conductive, structures on the surface of the polymer molding, the thermal treatment comprising the heating of the region of the surface to a temperature which corresponds at least to the melting temperature of the at least one polymer phase. In a preferred embodiment, the cooling of the thermally treated regions (until the polymer phases have solidified again) is followed by one (or else more than one) further thermal treatment of the same regions.

Preferably, the thermal treatment of the surface(s) of the polymer molding is effected by contact with a heated body, gas (e.g. hot air) or liquid, or by electromagnetic radiation or using the inventive device (which is described below). A person skilled in the art can select the means suitable in each case for partially melting a defined region of the surface.

It is possible here to perform the thermal treatment either after preceding production of the polymer molding, i.e. after the polymer molding has left the “mold”, or as early as in the course of production of such a molding in the mold. There are already known molds in which individual parts of a molding can be heated in a controlled manner in the mold, or kept hot for longer.

Preference is given, however, to using electromagnetic radiation for thermal treatment of the surface of the polymer molding. It is more preferred here to use laser radiation or IR radiation, more preferably laser radiation. It is possible here to use known lithography processes for controlled irradiation of defined regions of substrate surfaces. Processes for controlled irradiation of surfaces are known to those skilled in the art and are disclosed, for example, in EP 0 847 329 A or WO 02/079881 A. Particular preference is given to the use of a pulsed laser. Especially the use of pulsed laser radiation led surprisingly to a further improvement in conductivity.

Suitable lasers for the process according to the invention are He—Ne lasers, Nd:YAG lasers, carbon dioxide lasers (CO₂ lasers), carbon monoxide lasers (CO lasers), nitrogen lasers (N₂ lasers), argon ion lasers, helium-cadmium lasers (HeCd lasers), krypton ion lasers, oxygen ion lasers, xenon ion lasers, mixed gas lasers (for example containing argon and krypton), excimer lasers, metal vapor lasers (for example copper vapor lasers) and metal halide lasers (for example copper bromide lasers), preference being given to carbon dioxide lasers (CO₂ lasers) and Nd:YAG lasers.

Preference is given to heating a point on the surface of the polymer molding for 0.001 to 1 second. The duration of heating relates here to the period within which the surface of the polymer molding is in the molten state. This period can be selected easily by the person skilled in the art for the desired use and the polymers used.

More particularly, it is possible to adjust the surface resistance by the duration of the heating in which the surface is partially melted. The longer the surface is partially melted and the deeper the partially melted region extends into the surface, the more carbon nanotubes migrate to the surface, which increases the electrical conductivity of the structure.

The term “surface” as used here relates to a surface of a polymer molding, especially to the surface of the polymer phase of the polymer molding which comprises CNTs. What is crucial for the present invention is that the conductivity of the surface of a polymer molding is increased by treatment of the surface of the polymer phase which comprises CNTs. In one embodiment of the invention, it is possible, for example, to apply a layer of a polymer which comprises CNTs to a body and to treat the entire polymer layer (entire surface of the polymer phase) in accordance with the invention. Thus, no untreated surface of the CNT-containing polymer phase remains. The conductive layer thus obtained differs from a conductive, CNT-containing polymer layer which is applied to a polymer molding (for example by a coating process as described in US 2006/0062983 A1). As a result of the inventive treatment of the surface of the polymer phase, a higher CNT concentration of the polymer phase is present at the surface, while the concentration of CNTs decreases in the interior of the polymer phase with increasing distance from the surface. Preferably, the opposite surface of the polymer phase from the treated surface of the polymer phase (e.g. the side of the polymer layer which is bonded to the body) thus has a lower CNT concentration.

In another embodiment of the invention, only particular regions of a surface of the polymer phase are treated in accordance with the invention, in which case the CNT concentration of the adjacent, untreated regions of the same surface retain a virtually unchanged CNT concentration.

It is additionally preferred that the surface of the polymer molding is heated to a temperature which is sufficient to melt the polymer phase(s) but does not lead to noticeable vaporization of the polymer phase(s). The expression “noticeable vaporization” means here that the conductive structure produced is less than 1 micrometer, more preferably less than 500 nm, deep in the surface of the polymer molding.

The process according to the invention can be used especially for production of electronic circuits on the surface of the polymer molding. It is thus possible in a simple manner to produce especially very small components, for example in the form of MIDs (molded interconnected devices). It is possible here to produce the polymer moldings in accordance with the invention, for example, in a standard injection molding process in the form of any desired moldings, and then to produce the electrically conductive structures.

The invention further relates to a polymer molding comprising at least one polymer phase and between 0.01 and 10% by weight, preferably between 0.1 and 10% by weight, more preferably between 0.1 and 10% by weight, more preferably between 0.1 and 8% by weight and most preferably between 0.1 and 6% by weight of carbon nanotubes (CNTs) (based on the total mass of the polymer phase(s) of the polymer molding), said polymer molding having electrically or thermally, preferably electrically, conductive structures on the surface, the concentration of the CNTs in the regions of the conductive surface structures being higher than in the nonconductive surface regions. As described above, the nonconductive surface regions of the CNT-containing polymer phase likewise comprise CNTs. Preferably, the nonconductive surface regions have the same CNT concentration as before the production of the conductive structures, i.e. preferably the concentrations of CNTs used in accordance with the invention (see above), for example 0.01 to 10% by weight of CNTs.

Preferably, the polymer molding consists of the polymers described above, especially those mentioned as preferred. Especially preferably, the polymer molding comprises at least one polymer phase which comprises a polymer selected from the group consisting of: polycarbonate, polystyrene, acrylonitrile-butadiene-styrene (ABS), styrene-maleic anhydride (SMA), styrene-methyl methacrylate (SMMA), polymethyl methacrylate (PMMA), polybutylene terephthalate (PBT), polyethylene terephthalate (PET), nylon-6 (PA 6), nylon-6,6 (PA 66), nylon-6,4 (PA 64), nylon-12 (PA 12), aromatic polyamide and polysulfone, polypropylene.

Additionally preferably, the polymer molding comprises nanocomposites. Suitable nanocomposites and suitable amounts have been described above.

In a further preferred embodiment of the invention, the polymer molding has at least two separate polymer phases. More preferably, the polymer molding comprises at least two, more preferably two, polymer phases, in which case one polymer phase consists of polymers selected from the group consisting of polystyrene (PS), polymethyl methacrylate (PMMA) and acrylonitrile-butadiene-styrene (ABS), and thermoplastic polyesters such as polyethylene terephthalate (PET) or polybutylene terephthalate (PBT), and polycarbonate, and also mixtures thereof. The second polymer phase consists of polypropylene and/or polypropylene copolymers. Alternatively, the two polymer phases may consist of polystyrene and/or nylon-6 in combination with polyethylene and/or polypropylene. Particular preference is given to the use of polycarbonate in combination with polyolefins, especially polypropylene. The preferred proportions of polypropylene and/or polypropylene copolymers are described above.

The analysis of the finished polymer molding with regard to the polymer phase(s) present is described in the method section. The conductive structures (with elevated CNT content) on the surface of the polymer molding can, as already mentioned, be detected with customary optical test methods. More preferably, one of the polymer phases contains a higher proportion of carbon nanotubes (CNTs) than the other phase(s).

It is additionally preferred that the electrically conductive structures of the polymer molding extend not more than 10 μm, preferably not more than 1 μm, more preferably not more than 100 nm, into the interior of the polymer molding (calculated from the outer surface).

In a particularly preferred embodiment of the invention, the polymer molding comprises a polypropylene phase and a polycarbonate phase, preference being given to using between 50 and 80% by weight, more preferably between 60 and 80% by weight and even more preferably between 70 and 80% by weight of polypropylene, based on the total mass of the polymer mixture. Particularly suitable polycarbonates can be prepared as described, for example, in DE 13 002 66 or DE 14 957 30.

The inventive polymer molding can especially be configured such that the electrically conductive surface structures thereof are conductor tracks or electronic circuits. It is thus possible to use the polymer molding as a circuit board in an electronic component or device. It is possible to apply any desired components including electronic components to this circuit board by conventional processes, for example soldering, adhesive bonding, adhesive bonding, followed by braising, welding or ultrasound welding. It is also possible to attach them by an assembly procedure known to those skilled in the art, for example by means of a through-contacting operation. More particularly, it is possible to produce holes or bores in the circuit board, through which the components are conducted and are then mounted on the circuit board, especially the “backside” of the circuit board, for example by adhesive bonding or soldering. According to the invention, the components are brought into contact with the electrically conductive structures on the circuit boards, said electrically conductive structures, as described above, being regions with elevated CNT concentrations, which additionally preferably also have a metallic layer, preferably a copper layer.

A particularly advantageous inventive means of mounting or applying components on the inventive polymer moldings is explained in more detail herein. In short, this involves directly or indirectly, partially or fully melting the region of the polymer molding in which the component is to be mounted or applied, such that adhesion of the component is enabled. It has been found that, surprisingly, this simultaneously enables a bond of very good conductivity between the component and the polymer molding.

A further aspect of the invention relates to a device and to the use thereof for the above-described thermal treatment of at least one surface of the polymer molding to produce the conductive, especially the electrically conductive, structures on the surface of the polymer molding.

This device for producing a structure on a body to be processed has an energy source. The energy source has at least one electrode through which energy can be released. This energy released at least partially heats the body to be processed and enables the above-described melting of the polymer molding to produce the desired conductive structures.

The invention is particularly suitable when the body is a polymer molding composed of at least one polymer phase which comprises carbon nanotubes, since application of energy at quite specific positions in this body can alter the conductivity. It is thus possible to produce conductor tracks on a body to be processed without applying a conductive material layer and then etching away the regions of the conductive material layer that are not required. In this way, operating steps are dispensed with, the production of the circuit board is accelerated, and the economic viability of the production is thus increased.

The body to be processed can be produced particularly effectively when the energy source has at least two electrodes which can be placed onto the body to be processed, in which case the two electrodes can be used to conduct a current through the body to be processed or apply a voltage which heats the body to be processed and, as described in detail below, preferably melted it in defined regions, for example at the surface. As a result of this simple technical measure, in one possible embodiment, it is also possible to establish three-dimensional structures on the body to be processed, since the two electrodes can be attached, for example, on the frontside and on the backside of the body to be processed. For example, it is thus possible in a simple manner to burn holes into the body to be processed or, in the case of the above-described circuit board, to establish contacts between two planes. It is thus possible to produce multilayer circuit boards inexpensively with the device of the present invention.

To produce simple conductor tracks in one plane of the body to be processed, one electrode of the energy source can be fixed at one point, and the other electrode can be moved as desired on the body, which allows the electrical conductor tracks to be produced, especially in the case of a circuit board. Alternatively, however, it is also possible for both or several electrodes to be moved simultaneously. In a further embodiment of the invention, the two electrodes can also be kept at a predetermined distance from one another with a spacer, such that the two electrodes are both moved over the body to be processed in the production of the structure. The electrodes, or the parts thereof facing the polymer molding, for example in probe form, may in principle have any desired shape, the shape being selectable freely by the person skilled in the art with regard to the shape of the desired conductor tracks to be produced. The voltage applied or the current can also be selected freely, and the person skilled in the art can determine the suitable values in a simple empirical manner as a function of the polymer molding used, the composition thereof and the degree and region of the desired heating of the molding material. In many cases, for example, a voltage of more than 500 V, especially of 1000 V or more, will be favorable.

In a preferred embodiment of the invention, a first electrode is attached in a first region of the polymer molding (or the surface thereof) at which conductivity already exists or has been produced, while a second electrode, proceeding from a point on the polymer molding (or the surface thereof) which is within the same conductive region or which is connected to this region via a conductive region (for example a conductor track), is moved over the polymer molding (or the surface thereof) to produce a (new) conductor track, to enlarge the conductive region or to connect two existing conductive regions (for example conductor tracks) to one another. This procedure enables great flexibility in the production or configuration of the conductive structures on the polymer molding.

The device according to the present invention can, in one possible embodiment, be incorporated particularly effectively into a plotter, into a matrix printer or into a probe. In a process for producing a structure on a body to be processed, the body to be processed is at least partially heated by an energy source with at least one electrode provided for release of energy.

In the process according to the invention, the aforementioned apparatus features can be employed to like effect.

The invention is described in detail hereinafter with reference to two nonrestrictive working examples. The drawings show:

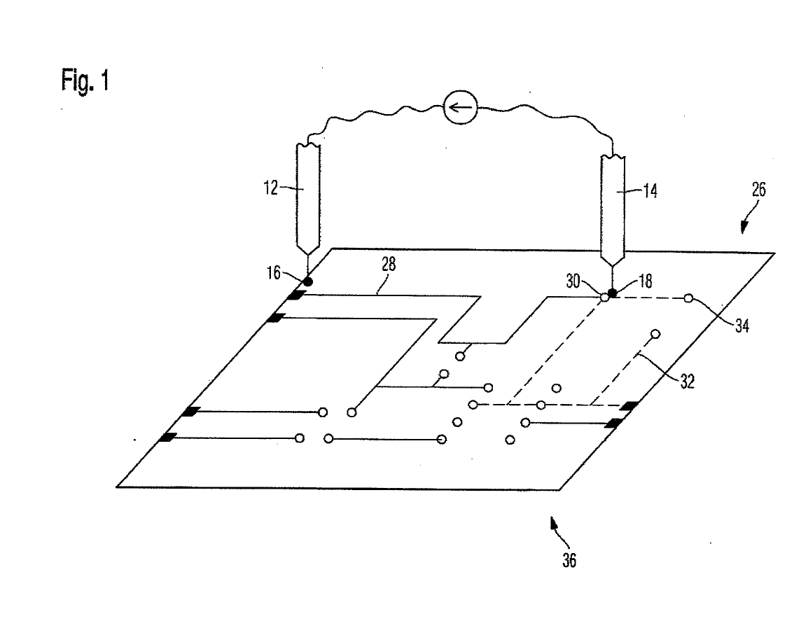

FIG. 1 an apparatus comprising a device according to a first working example of the present invention;

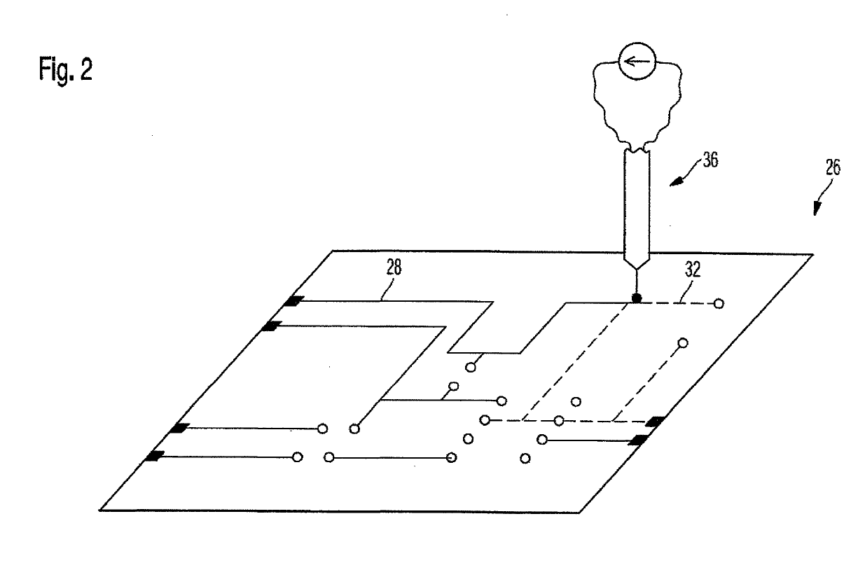

FIG. 2 an apparatus comprising a device according to a second working example of the invention;

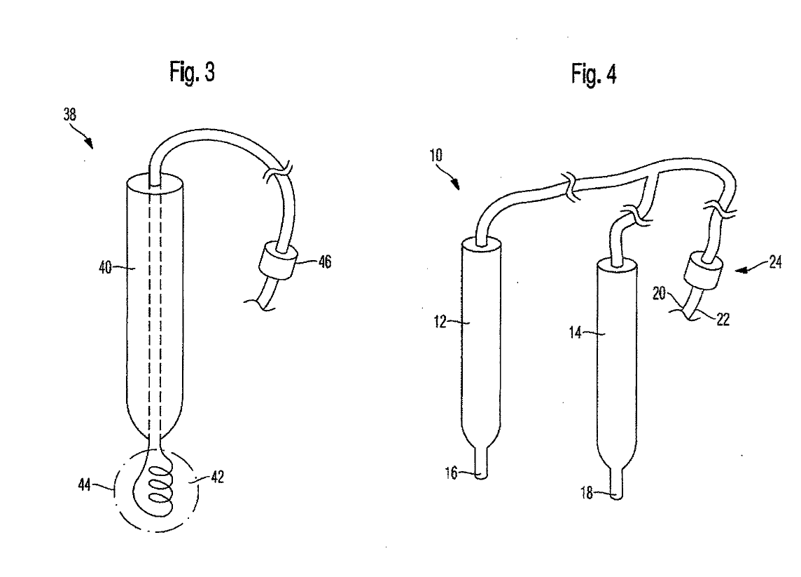

FIG. 3 the device according to the second working example of the invention; and

FIG. 4 the device according to the first working example of the invention.

In the figures, the following reference numerals are used:
10 device
12, 14 probes
16, 18 contact probe
20, 22 contact plug
24 plug
26 polymer body
28 conductor track
30 surrounding region
32 drawn lines
34 contact site
36 underside
38 device
40 probe
42 heating coil
44 protective body
46 plug

In a first working example of the invention, which is shown in FIGS. 1 and 4, the device 10 has a first probe 12 and a second probe 14. Each probe has, on its underside, a contact 16, 18, each of which is electrically connected to a contact 20, 22 of a plug 24.

When the contacts 16, 18 of the probes 12, 14 are placed onto a polymer body 26 composed of at least one polymer phase containing carbon nanotubes, it is possible to heat the polymer body 26 in a controlled manner when the contacts 16, 18 of the probes 12, 14 are spaced apart from one another and a current is passed through the polymer body 26. The controlled heating of the polymer body 26 makes it possible to apply conductor tracks 28 thereto, which can likewise conduct the current from the contacts 16, 18 of the probes 12, 14. When, for example, the first probe 12 with the first contact 20 is fixed at a fixed position and only the second probe 14 with the second contact 18 is moved on the circuit board, the distance between the conductor track already produced and the current position of the second contact 18 as a function of the movement rate is very low. This small distance results in a small resistance between the conductor track 28 and the second contact 18, which heats the conductor track 26 in a surrounding region 30 around the second contact 18 of the second probe 14, and the conductor track 28 thus continues.

In a practical manner, in one possible embodiment, the conductor tracks to be produced on the polymer body 26 can be indicated with predrawn lines 32 in order to support the production operation for the circuit board. In addition, contact sites 34 can be produced on the polymer body 26, which penetrate through the polymer body 26. For this purpose, it is necessary merely to remove the second probe from the polymer body 26, and to mount it on the underside 36 of the polymer body 26 approximately below the conductor track 28 already produced. As a result, a current is passed again via the conductor track 28 between the two contacts 16, 18 of the two probes 12, 14, which produces the contact site 34 through the polymer body 26.

FIGS. 2 and 3 show a device according to a second working example of the invention. According to these, the device 38 comprises a probe 40 adjoined at the lower end thereof by a heating coil 42. This heating coil is preferably surrounded by a protective body 44. The protective body may be intended to regulate the heating, or else to protect the heating coil 42 from soiling or other external influences. In addition, the device 38 according to the second working example of the invention has a plug 46 with which the heating coil 42 can be supplied with electrical energy.

In use, the device 38, as shown in the first working example, is drawn over the predrawn lines 32, so as to give rise to the conductor tracks 28 already discussed. In the present embodiment, it is unnecessary to position a first probe at a predetermined site on the polymer body 26.

The invention can produce structures on a body in a simple manner, without any need to apply a base material and to remove the sites on the base material which are not required. This dispenses with process steps in the production, and so the production of the body to be processed becomes more economically viable. Accordingly, a further aspect of the present invention relates to the use of the above-described devices, apparatuses and processes for producing (conductive) structures on polymer moldings.

The above devices, apparatuses and processes offer particular advantages in the use of the inventive polymer moldings with conductive structures on the surface, and processes for production thereof are also described.

For industrial applications, electronic components have to be applied to the conductive structures of the inventive polymer moldings. For this purpose, it is firstly necessary to ensure a sufficient stability of the components on the circuit boards, and secondly that an electrically conductive connection is established between the conductor tracks and the electronic components.

In the context of the present invention, it has been found that, surprisingly, particularly advantageous circuit board arrangements can be produced when polymer moldings containing CNTs are used as circuit boards, and electronic components are applied to the conductive structures or conductor tracks produced by thermal treatment using an inventive organic adhesive composition which likewise comprises CNTs. Surprisingly, the use of a CNT-containing adhesive on a CNT-containing circuit board enables particularly good fixing of the electronic components. In contrast, the use of adhesives containing conductive substances, for example silver particles, leads to poor adhesion on CNT-containing substrates.

It has been found here that particularly good electrical properties are achieved by the combined use of a CNT-containing adhesive and a CNT-containing circuit board.

Surprisingly, it is additionally possible to mount components in a very reliable and durable manner with a low time requirement by producing a bond which comprises CNT-comprising material and/or by means of a solder bond on a circuit board which comprises a CNT-containing polymer molding, as explained in detail hereinafter. The term “bond” encompasses any adhesion or attachment using CNT-comprising material, especially a CNT-containing polymer material. The CNT-comprising material is more preferably the material of the polymer molding described herein.

A preferred circuit board arrangement therefore comprises at least one circuit board with at least one electrically conductive track and at least one electronic component, said circuit board comprising a polymer molding containing 0.1-10% by weight, more preferably 1-10% by weight and even more preferably 5-10% by weight of carbon nanotubes (CNTs), based on the mass of the polymer phase(s), and said at least one electronic component more preferably being bonded to at least one electrically conductive track of said circuit board by an organic adhesive composition comprising 0.05-10% by weight, more preferably 0.1-10% by weight, more preferably 1-10% by weight and most preferably 5-10% by weight of carbon nanotubes (CNTs), based on the mass of the adhesive composition, and/or by a bond which comprises material comprising carbon nanotubes (CNTs), especially one or more polymer phases comprising carbon nanotubes (CNTs), and/or by a solder bond. The electrically conductive tracks are formed here by regions of the surface of the polymer molding which have an increased CNT concentration.

For the circuit board arrangement, it is possible to use all inventive adhesive compositions which are described here. Particular preference is given to using a urethane acrylate adhesive. More preferably, the bond between the at least one electrically conductive track and the at least one electronic component has an electrical resistance of less than 50 ohms.

The invention further relates to an adhesive composition comprising 0.05-10% by weight of carbon nanotubes (CNTs). The adhesive composition can be effected by mixing the CNTs with the adhesive components. Processes suitable for this purpose are known to those skilled in the art.

Preferably, it is possible here to use those adhesives which comprise a substance which, under the influence of radiation or heat, reacts or releases a substance which reacts with the reactive constituents of the adhesive or triggers or catalyzes the polymerization thereof. The adhesive composition preferably comprises acrylate adhesives, phenol-formaldehyde resin adhesives, silicone adhesives or polyurethane adhesives, preferably acrylate adhesives. The adhesive composition is more preferably selected from the group consisting of cyanoacrylate adhesives, methyl methacrylate adhesives, urethane acrylate adhesive, butyl acrylate and radiation-curable acrylate adhesives; more particularly, a urethane acrylate adhesive is used. Especially preferably, the inventive adhesive composition consists only of CNTs and the aforementioned adhesives or mixtures thereof.

The electrical resistance of the adhesive composition is preferably less than 100 ohms, especially less than 50 ohms.

The present invention additionally relates to the use of an inventive adhesive composition for electrically conductive bonding of an electronic component to another electrically conductive component or molding, especially to an electrically conductive track or an electrically conductive region on a conductor track.

The invention additionally relates to a process for applying at least one electronic component to a circuit board, comprising the following steps:

a) providing a circuit board with at least one electrically conductive track or at least one electrically conductive region, said circuit board being a polymer molding containing 0.1-10% by weight of carbon nanotubes (CNTs), based on the mass of the polymer phase(s),
b) providing at least one electronic component, and
c) bonding, preferably thermally and/or electrically conductively bonding, the electronic component to the electrically conductive track or the at least one electrically conductive region using the inventive adhesive composition and/or by establishing a bond which comprises material comprising carbon nanotubes (CNTs), especially one or more polymer phases comprising carbon nanotubes (CNTs), and/or by establishing a solder bond.

Preferably, in step a) of the process, the polymer molding with electrically conductive structures is produced by the process according to the invention as described above. Preference is given here to using the inventive device to produce a conductive structure.

Suitable electronic components which can be applied to circuit boards are known to those skilled in the art. These components may typically have “metallic legs” which must or can be brought into contact with the circuit board or the conductive structures present thereon. Examples of electronic components are especially surface-mountable components (surface-mounted devices, SMDs). Surface-mounted devices (SMDs) can be mounted on a circuit board especially via their terminals, especially their terminal surfaces. The mounting can be effected via surface-mounting technology processes known to those skilled in the art. Procedures for mounting of components, especially SMDs, which give rise to outstanding properties in combination with circuit boards which comprise a polymer molding comprising CNTs are elucidated above and below. The SMDs may, for example, be resistors, coils, capacitors, especially ceramic capacitors, tantalum electrolytic capacitors, aluminum electrolytic capacitors, quartz crystals, diodes, transistors, voltage regulators, light-emitting diodes, potentiometers, trimmers, sensors, optocouplers, reed contacts or integrated circuits.

More particularly, the electronic components may have terminates on at least one face, especially one, two, three or four faces, especially side faces, of the housing. The term “leg of a component” and the terms “section of the electronic component”, especially “section of the electronic component which is contacted with the at least partially molten section of the polymer molding or of the electrically conductive track or of the electrically conductive region”, as used in the context of the present application, includes especially terminates of surface-mounted devices (SMDs), which may be present, for example, in the form of small rods or platelets, or in the form of terminate surfaces. The terminates may preferably comprise one or more bends, and be present, for example, in “gull-wing” or “J-lead” forms.

Electronic components which can be applied to circuit boards may have SMD designs or SMD housings.

In the context of the present invention, it is possible for one or more components which may especially have a design or a housing selected from MELF (metal electrode faces), chip design, V-chip design, SOD (small outline diode), SOT (small outline transistor), DIL (dual-in-line), SOIC (small outline integrated circuit), SOP (small outline package), PLCC (plastic leaded chip carrier), QFP (quad flat package), MLP (micro leadframe package), MLF (micro lead frame), QFN (quad flat pack no leads), LGA (land grid array), BGA (ball grid array) and combinations thereof to be mounted on a circuit board, especially on a circuit board comprising a polymer molding comprising carbon nanotubes.

In the context of the present invention, the components, especially the SMDs, can be mounted, for example, using adhesives, especially adhesive compositions comprising carbon nanotubes, which comprise preferably 0.05 to 10% by weight of carbon nanotubes, and/or using solder bonds and/or by means of a bond which comprises material comprising carbon nanotubes.

The solder bond can especially be established using a solder, especially a solder paste, which may comprise, for example, tin and/or lead. The soldering process employed may be a soldering process known to those skilled in the art.

Very good securing can be obtained in the case of mounting of the component by employment of the reflow soldering process. It is possible here firstly to apply a solder to the circuit board in the form of a solder paste, then to apply the component to a site on the circuit board provided with solder paste, and thereafter to heat the solder paste at least to a temperature at which the solder paste melts.

Adhesives and/or solder pastes (for production of a solder bond, especially in the case of reflow soldering) can be applied in accordance with general specialist knowledge. Very good results can be used especially when solder paste or adhesive is applied by means of screen printing, or is applied in small portions, especially using metering devices.

Since the inventive adhesive composition is conductive, it is also possible for adhesive to be present between the legs and the conductive structure. In order to apply the components to the circuit board, the legs of the components can, for example, be immersed into the adhesive composition and then placed onto the circuit board. In this case, the amount of adhesive has to be chosen such that sufficient stability is obtained between the component and the circuit board, but no adjacent conductor tracks come into contact with adhesive. The adhesive composition can then be cured in a customary manner, for example using a UV lamp.

The bonding, preferably the thermally and/or electrically conductive bonding, of the electronic component to the polymer molding or to the at least one electrically conductive track or the at least one electrically conductive region can also be effected by establishing a bond which comprises material comprising carbon nanotubes (CNTs), especially one or more polymer phases comprising carbon nanotubes (CNTs). In this embodiment of the invention, it is particularly advantageous to mount the component in one step, optionally in the same step as the production of the conductor tracks on the polymer molding, the permanent bonding and the avoidance of solder.

In addition, the bonding of the electronic component to the polymer molding or the at least one electrically conductive track or the at least one electrically conductive region can also be effected by establishing a bond which comprises material comprising carbon nanotubes (CNTs), in combination with use of an inventive adhesive composition and/or of a solder bond.

More particularly, at least one first section of the component can be mounted using the inventive adhesive composition, and additionally at least one second section of the component with establishment of a bond which comprises material comprising carbon nanotubes (CNTs). The suitable method of bonding in each case can be selected by a person skilled in the art on the basis of his general specialist knowledge, and on the basis of the circuit board arrangement to be produced in each case and the electronic components to be mounted.

In the context of the present application, the term “material comprising carbon nanotubes (CNTs)” comprises especially monophasic or polyphasic compositions which comprise carbon nanotubes, especially compositions which comprise one or more polymers and carbon nanotubes, especially at least two or more phase-incompatible polymers and carbon nanotubes.

To establish a bond which comprises material comprising carbon nanotubes (CNTs), it is first possible to supply energy to at least one section, especially to a surface section, of the CNT-comprising polymer molding or of the electrically conductive, especially CNT-comprising, track or of the electrically conductive, especially CNT-comprising, region, which at least partially melts the section of the polymer molding, of the electrically conductive track or of the electrically conductive region to which energy has been supplied.

Energy can be supplied especially by contact with a heated body, gas (e.g. hot air) or liquid, or by means of electromagnetic radiation. A person skilled in the art can select the means suitable in each case for supplying energy or for partially melting a defined region of the surface.

In the context of the present application, the expression “at least partially melts” includes not only partial or complete melting, but also any incipient melting, especially any partial incipient melting, and any change in the polymer molding, in the electrically conductive track or in the electrically conductive region which enables the section (or a subregion thereof) of the component to be mounted to be sunk into the material of the polymer molding or of the conductive track or of the electrically conductive region, or wetting thereby. More particularly, the section of the polymer molding, of the conductive track or of the conductive region can be heated to a temperature which corresponds at least to the melting temperature of the material or at least to the lowest melting temperature of the particular materials of the polymer molding or of the conductive track or of the electrically conductive region.

The step of supplying energy to at least one section, especially to a surface section, of the polymer molding comprising CNTs, of the electrically conductive track or of the electrically conductive region can especially be effected by heating a section of the electronic component which is in contact with the polymer molding, the electrically conductive track or the electrically conductive region, or is designed for contacting with a section of the polymer molding, of the electrically conductive track or of the electrically conductive region, and is contacted therewith after heating, and/or by heating at least a section of the polymer molding, of the electrically conductive track or of the electrically conductive region. The expression “section of an electronic component”, especially “section of the electronic component which is contacted with the at least partially molten section of the polymer molding or of the electrically conductive track or of the electrically conductive region”, may, in the context of the present invention, comprise any sections of an electronic component selected by a person skilled in the art for mounting on a circuit board. More particularly, these expressions include one or more terminates of any form of a surface-mounted device (SMD), especially in the form of a terminate surface, preferably in the form of a “leg” or one or more terminates of another component, which may especially be in the form of a “leg”. Such sections of components, especially terminates of SMDs, may comprise or consist of one or more metals, especially metallic alloys.

The heating of the section of the electronic component and/or of the at least one section of the polymer molding, of the electrically conductive track or of the electrically conductive region can be effected in a direct manner, by the action of an energy source, for example electromagnetic radiation, especially laser radiation or IR radiation, on the particular section of the electronic component and/or of the at least one section of the polymer molding, of the electrically conductive track or of the electrically conductive region, or can be effected indirectly, by the action on a device or a further section of the component which is connected in a thermally and/or electrically conductive manner to the section of the electronic component to be heated.

In a next step, a section of the electronic component, for example a leg of the component, can be contacted with the at least partially molten section of the polymer molding, of the electrically conductive track or of the electrically conductive region.

In the case that they come into contact, it is especially possible that the section of the component to be mounted is already present on the circuit board, especially the polymer molding, preferably the electrically conductive track or the electrically conductive region, and can come into contact there with the melt. For example, the section of the component to be mounted can be heated, which leads, as a result of the contact with the heated section, to melting of material which comprises CNTs and adjoins this component section, especially of the polymer molding, of the electrically conductive track or of the electrically conductive region, and/or material which comprises CNTs and adjoins the section of the component, especially of the polymer molding, of the electrically conductive track or of the electrically conductive region can be melted, which leads to the melt comprising CNTs coming into contact with the section of the component to be mounted.

More particularly, it is also possible for a section of the polymer molding comprising CNTs, which is adjacent to an electrically conductive track or an electrically conductive region, to be partially melted in such a way that, after the formation of the bond, an electrically conductive contact is present between the bond or the component and the electrically conductive track or the electrically conductive region. It is optionally possible, after the formation of the bond by the aforementioned process, to establish an additional electrically conductive track which connects the bond to the electrically conductive track or the electrically conductive region, especially in an electrically or thermally conductive manner.

In a next step, a bond is then formed, especially an electrically conductive bond, between the section of the electronic component and the at least one section of the polymer molding, of the electrically conductive track or of the electrically conductive region. It is very advantageous that the bond can be formed even without further measures or steps, in a simple manner on cooling of the melt which is in contact with a section of the component. Optionally, a person skilled in the art can take further measures which further improve the contact between the melt and the section of the component.

For example, in one embodiment, the component can be applied to the circuit board, preferably to the polymer molding, in which case the section of the component to be mounted is preferably in complete or at least partial contact with the electrically conductive track or the electrically conductive region. Subsequently, it is then possible for a light or heat source (for example a laser) to act on a section of the component, for example on a leg of the component, which is connected with thermal conduction to an adjoining region of the polymer molding, especially of the electrically conductive track or of the electrically conductive region, such that the latter melts and the melt comes into contact with the leg.

Additionally or alternatively to action on a section of the component, it is possible for a light or heat source (for example a laser) to act on a region of the polymer molding, especially of the electrically conductive track or of the electrically conductive region, adjoining the section of the component, for example a leg of the component, such that said electrically conductive region melts and the melt comes into contact with the leg.

In the course of cooling and concurrent solidification of the melt, a bond is then formed between the section of the component, for example of a leg, and the circuit board, especially the polymer molding, preferably the electrically conductive track or of the electrically conductive region. In this way, it is possible in a very advantageous manner and with a low level of labor simultaneously to secure a component and to provide a bond with very good electrical conductivity.

In a further embodiment, a light or heat source (for example a laser) can act on the polymer molding, especially an electrically conductive track or an electrically conductive region thereof, which results in locally limited melting, especially of a surface section thereof, at the point on which light or heat acts. Subsequently, one or more sections of the component to be mounted, for example one or more legs of the component, are then contacted with this melt-comprising site. In the course of cooling and the concurrent solidification of the melt, a bond is formed between the section of the component, for example of a leg, and the circuit board, especially the polymer molding, preferably the electrically conductive track or the electrically conductive region. In this way, it is possible in a very advantageous manner and with a low level of labor to simultaneously secure a component and to provide a bond with very good electrical conductivity.

If desired, it is possible in a further embodiment to heat both a section of the component, for example a leg thereof, and a section of the circuit board, especially of the polymer molding, especially of an electrically conductive track or of an electrically conductive region thereof.

The heating can be effected especially to a temperature above the melting point of the material of the section at which the component is to be mounted to form a bond. The longer the surface of the polymer molding is partially melted, and the greater the amount of energy used, the deeper the partially melted region extends, as explained in detail above, into the surface, and the more carbon nanotubes migrate to the surface, which increases the electrical conductivity of the structure. The selection of the duration of the heating and of the amount of energy supplied can, in this way, influence the conductivity of the bond between the section of the component and the polymer molding, especially an electrically conductive track or of an electrically conductive region thereof.

Very good results and a high reliability of the mounting can be obtained especially when the above-elucidated step of supplying energy or of heating is effected using a laser.

Suitable lasers for the process of applying the electronic component are: He—Ne lasers, Nd:YAG lasers, carbon dioxide lasers (CO₂ lasers), carbon monoxide lasers (CO lasers), nitrogen lasers (N₂ lasers), argon ion lasers, helium-cadmium lasers (HeCd lasers), krypton ion lasers, oxygen ion lasers, xenon ion lasers, mixed gas lasers (for example containing argon and krypton), excimer lasers, metal vapor lasers (for example copper vapor lasers) and metal halide lasers (for example copper bromide lasers), preference being given to carbon dioxide lasers (CO₂ lasers) and Nd:YAG lasers.

The bond may comprise or consist of one or more polymer phases comprising carbon nanotubes (CNTs), and this can be varied, if desired, by a person skilled in the art through the selection of the duration of the heating and of the amount of energy supplied, and the material of the polymer molding, which has been elucidated in detail above.

In addition, the bond can be produced in such a way that the bond comprises or consists of at least one polymer phase comprising carbon nanotubes (CNTs) which has a content of 0.05-10% by weight of carbon nanotubes (CNTs), preferably of 0.1-10% by weight of carbon nanotubes (CNTs), preferably of 0.2-10% by weight of carbon nanotubes (CNTs), based in each case on the mass of the polymer phase.

The expression “component bonded to the at least one electrically conductive track or the at least one electrically conductive region by an adhesive composition and/or by a bond and/or by a solder bond” can especially include the possibility that the component is in direct contact and/or in contact via one or more connecting devices with the adhesive composition and/or the bond and/or the solder bond, and also that the at least one electrically conductive track or the at least one electrically conductive region is in direct contact and/or in contact via one or more connecting devices with the adhesive composition and/or the bond and/or the solder bond.

In addition, an (electronic) component can be mounted especially by first mounting a connecting device comprising electrically conductive material on a circuit board, especially on a circuit board containing a polymer molding comprising carbon nanotubes, in such a way that the connecting device is in electrically conductive contact with one or more electrically conductive track(s) and/or electrically conductive region(s). Subsequently, the (electronic) component is applied to this connecting device, for example by soldering or adhesive bonding, such that the (electronic) component is bonded in an electrically conductive manner to the one or more electrically conductive track(s) and/or electrically conductive region(s).

The connecting device comprising conductive material may be a device comprising or consisting of one or more metal(s) or alloys. More particularly, the connecting device comprising conductive material may be a loop or a layer on the polymer molding on which, for example, a surface-mounted device (SMD) is mounted, for example by adhesive bonding or soldering.

In one embodiment, the circuit board arrangement may comprise a solder bond, optionally in combination with a bond comprising material comprising CNTs and/or a bond produced by an organic adhesive composition comprising CNTs. The solder bond can produce an electrically conductive bond between at least one section of a component, especially at least one section of an SMD, more especially at least one terminal of an SMD, and the polymer molding, especially the electrically conductive tracks and regions on and/or in the polymer molding. More particularly, the solder bond can connect the component to a layer which comprises metal, especially copper and/or tin, which is arranged on the circuit board, especially the polymer molding, and is in electrically conductive contact with an electrically conductive track or an electrically conductive region thereof, in an electrically conductive manner.

A further aspect of the invention relates to a circuit board arrangement, wherein the circuit board comprises an inventive polymer molding. The inventive polymer molding can be produced and provided with electrically conductive structures or conductor tracks as described above. In this circuit board arrangement, components, especially those mentioned above, can be mounted by one of the procedures specified above. In order to further increase the electrical conductivity of the structures with elevated CNT concentration, it is preferred in one possible embodiment to apply a metal layer, preferably a copper layer. Thus, a metal layer is present on the conductive structure composed of polymer with elevated CNT concentration (compared to the CNT concentration in the nonconductive regions). As described above, in one embodiment of the invention, the entire surface, or one of several surfaces of the CNT-containing polymer phase, is treated in accordance with the invention, such that no nonconductive surface regions remain. The resulting conductive surfaces can likewise be provided with a metal layer. This enables a multitude of electronic applications.

In the context of the present invention, it has been found that, surprisingly, the polymer moldings containing the electrically conductive structures can be used directly in an electroplating process, and a copper layer can be applied directly to the polymer moldings in a controlled manner. Compared to electroplating processes used to date for polymer moldings, the following steps which have been necessary to date are therefore dispensed with: etching, activating and producing an intermediate layer (see, for example, “Kunststoffgalvanisierung” [“Electroplating of polymers”], LPW-Taschenbuch für Galvanotechnik [LPW Handbook for Electroplating Technology], Volume 1, Verfahrenstechnik [Process Technology], 13^{th} edition 1988, pages 443 to 449). It is therefore possible in accordance with the invention, for example, after the cleaning of the surface of the polymer molding, to form the layer directly.

Surprisingly, it is also possible to coat the inventive polymer moldings with a metal by means of bathless electroplating. It is possible here to dispense with the customary immersion of the workpieces to be coated into electrolyte-filled vessels, known as electroplating baths. Instead, the electrolytes required are absorbed by absorptive materials, which are in turn held by coating tools. By pressing the tools onto the surface to be coated, especially component surface, the deposition is enabled, and the direct current required is likewise transferred by the tool.

In this case, the circuit board containing the conductive structures is introduced in a customary manner into an electrolytic electroplating bath (see, for example, “Kunststoffgalvanisierung”, LPW-Taschenbuch für Galvanotechnik, Volume 1, Verfahrenstechnik, 13^{th} edition 1988, pages 443 to 449). The electroplating bath comprises, for example, a copper(II) sulfate solution with an anode.

The application of a negative voltage (cathode) to the electrically conductive structures on the surface of the polymer moldings and to the counterelectrode of copper allows copper to be deposited on the structures from the solution in a controlled manner to form a metallic layer. The electrolyte solutions suitable for this purpose, the electrical potential and the suitable duration of the deposition can be selected by the person skilled in the art according to the application and the desired nature of the conductor tracks. Surprisingly, the use of the inventive amounts of CNTs leads to controlled deposition of the copper on the conductive structures with elevated CNT concentration already present on the surface of the polymer molding. In the case of use of the inventive CNT contents in the polymer molding, the potential is not sufficiently high for deposition of copper at the points on the surface of the polymer molding which have not been treated thermally and therefore do not contain any conductive structures. In contrast, when higher CNT contents are used in the polymer moldings, there may be uncontrolled deposition of copper over the entire surface of the polymer molding. On the other hand, the inventive minimum amount of CNTs in the polymer molding is necessary to obtain conductive structures which enable a sufficiently high potential for deposition of the copper onto the conductive structures.

With the process according to the invention, it becomes possible in a simple manner to obtain conductive structures on a circuit board without any need, for example, to cover regions which are not to be coated with copper. Since the copper is applied in a controlled manner to the conductive structures already present, it is additionally also unnecessary to subsequently perform any etching process to remove excess copper.

A circuit board arrangement preferred in accordance with the invention comprises at least one circuit board comprising at least one electrically conductive track, said circuit board comprising a polymer molding containing 0.1-10% by weight of carbon nanotubes (CNTs), based on the mass of the polymer phase(s), and said at least one electrically conductive track comprising a copper layer. The term “copper” (or “tin” or “gold”) in the context of the present application includes pure copper (or tin or gold), copper (or tin or gold) comprising customary impurities, and alloys and compositions which comprise copper (or tin or gold), for example at least 20% by weight, especially at least 90% by weight of copper (or tin or gold), more especially at least 98% by weight of copper (or tin or gold), based on the total weight of the alloy or composition.

Optionally, the copper layer may be provided completely or in sections with a further layer which comprises or consists of one or more metals or alloys. More particularly, the copper layer may have a layer comprising tin or gold, and especially be tin-plated or gold-plated. A layer comprising tin or gold can especially be arranged at sites at which sections of the component to be mounted, preferably SMD terminals, are arranged.

In addition, it is preferred that the circuit board arrangement comprises at least one electronic component which is bonded to at least one electrically conductive track of said circuit board by an inventive organic adhesive composition, as described below, and/or by establishing a bond which comprises material comprising carbon nanotubes (CNTs), and/or by establishing a solder bond. The solder bond can produce a bond between a component, especially between at least one section of a component, preferably between at least one section, for example at least one terminal, of an SMD, and the polymer molding. More particularly, the solder bond can bond the component to a layer which comprises metal, especially copper, which has been applied to the conductive structures with elevated CNT concentration on the surface of the polymer molding, for example as described above. The soldering processes used for this purpose may, for example, be processes known to those skilled in the art, especially reflow processes.

The invention also relates to a process for producing an inventive circuit board arrangement, comprising the steps of:

a) providing a polymer molding composed of at least one polymer phase which comprises carbon nanotubes (CNTs);
b) thermally treating at least one surface of the polymer molding to produce the conductive structures on the surface of the polymer molding, the thermal treatment comprising heating to a temperature which corresponds at least to the melting temperature of the at least one polymer phase, and
c) optionally electroplating the electrically conductive structures. If desired, it is also possible to electroplate only some regions of the electrically conductive structures.

Additionally preferably, in the process for producing an inventive circuit board arrangement, in an additional step d), at least one electronic component is bonded to at least one conductor track of the circuit board using an inventive adhesive composition and/or bonded to at least one conductor track of the circuit board by establishing a bond which comprises material comprising carbon nanotubes (CNTs), and/or bonded to at least one conductor track of the circuit board, especially in an electrically and/or thermally conductive manner, by establishing a solder bond.

In a further aspect of the present invention, it is possible, in the case of production of the inventive polymer molding, for example, by injection molding, to provide elevated or depressed regions, which can serve, for example, as conductor tracks or else for securing of components. Such regions can be configured, for example, as clamps, clips, bores or the like, and enable simple securing or clamping of the components. More preferably, it is then possible to directly or indirectly heat the region of the polymer molding used for securing, in order to obtain the above-described (conductive) bond between the polymer molding or a region thereof and the component.

In a further aspect of the invention, the polymer molding comprises at least one polymer phase containing carbon nanotubes (CNTs), said polymer molding having electrically conductive or thermally conductive structures on the surface, the concentration of the CNTs in the regions of said electrically conductive surface structures being higher than in the electrically nonconductive surface regions, said electrically nonconductive surface regions comprising CNTs. In this context, the expression “concentration of the CNTs in the regions of the electrically conductive surface structures” and “electrically nonconductive surface regions” encompasses the possibility that the outer surface layer is examined for CNT content down to a depth of 10 μm, preferably down to 1 μm.

### METHODS

To determine the parameters of the inventive polymer moldings, the following methods are used:

The electrical surface conductivity is determined by measurement of the surface resistance with a “Metra Hit Plus” ohmmeter from Gossen Metrawatt GmbH according to the manufacturer's instructions. Both the resistance on the untreated surface and at each of the different sites of the laser-treated surface sections were measured by means of two electrodes at a distance of 2 mm. For comparison, the surface was mechanically removed at one site, and the electrical resistance in the material was measured.

The analysis as to whether a polymer molding has separate polymer phases can be effected using differential scanning calorimetry (DSC) to DIN EN ISO 11357. In this case, the number of polymer phases can be determined with reference to the phase transitions when the polymer molding is melted.

The melting temperature of the polymer phases or of the polymer molding can be determined to DIN EN ISO 3146.

The total content of CNTs in the polymer molding can be determined by the pyrolytic test method to DIN EN ISO 3451.

### EXAMPLES

### 1. Production of a Polymer Molding Containing Conductive Structures

A polymer mixture is produced from 75% polypropylene (Repol HP-12 from Reliance, India), 3.75% CNT (Baytubes C 150 P, from Bayer) and 21.25% by weight of polycarbonate (Makrolon 2805, from Bayer).

The mixture is melted and mixed in a ZSE 27/44D twin-screw extruder, from Leistritz, Nuremberg, with a diameter of 27 mm and an L/D ratio of 44 with a throughput of 10 kg/h and a power of 18 kWh. In the extruder, a temperature profile rising from 200° C. to 260° C. was established. This was followed by pelletization.

The polymer molding was shaped in the injection molding process (instrument type: Arburg 270) at a temperature of 220-240° C. in the form of disks with diameter 4 cm. For the thermal treatment a CO₂ laser was used.

The measurements of the surface resistances are reported in the table below.

TABLE

| Measurement | Surface | | | | Measurement |
|---|---|---|---|---|---|
| site | resistance | | | Mean | unit |
| Untreated | Zero conductivity (<10 MOhm) | | | | |
| Laser trace 2 | 133 | 122 | 146 | 1.34 | kOhm |
| Laser trace 3 | 64.3 | 58.9 | 69.1 | 64.1 | kOhm |
| Laser trace 4 | 23.2 | 21.2 | 24.4 | 22.9 | kOhm |

| | |
|---|---|
| Ground off | Zero conductivity (<10 MOhm) |

### 2. Production of a Circuit Board Arrangement with Electronic Components

### Example a

First, an inventive adhesive composition is prepared. This consists of 35 g of Photobond PB 437 (manufacturer: Delo, Germany), 0.35 g of Nanocyl 7000 (manufacturer: Nanocyl, Belgium). The components of the adhesive composition are stirred at 45° C. for 20 min using an IKA RH-KT/C hotplate with a stirrer (Heidolph RZ RO/4) at 300 rpm.

To determine the electrical resistivity, the adhesive was applied to a nonconductive surface and cured under a UV lamp (Siemens 6ES5985-1AA11 UV lamp) for 7 min. Subsequently, the Messcontrol M-860 D measuring instrument was used to measure a resistivity of 57 Ohm/cm.

In order to apply a diode to a circuit board, the metal legs of the diode were immersed into the adhesive composition and the diodes were contacted with the circuit board, such that the adhesive droplet produces a bond between the conductor track and the legs. Curing with the UV lamp gave a firm bond. After applying a voltage of 50 V, the diode glowed.

### Example b

In order to apply a diode to a circuit board comprising a polymer molding comprising carbon nanotubes, the diode was brought into contact with the circuit board, and a laser was used to partially melt one or more sites on the polymer molding adjacent to a leg of the diode, such that melt produces a bond between the conductor track and the legs. After cooling to 20° C., a mechanically durable and electrically conductive bond was obtained.

Preferred embodiments of the invention are described hereinafter. The inventive polymer moldings can be used for the inventive circuit board arrangements. The inventive device is suitable for thermal treatment of the surface of the polymer molding (step b of the process for producing conductive structures).

1. Process for producing conductive structures on the surface of nonconductive or only low-conductivity polymer moldings, comprising the following steps:

a) providing a polymer molding composed of at least one polymer phase which comprises carbon nanotubes (CNTs);
b) thermally treating at least one surface of the polymer molding, especially of a surface of the CNT-containing polymer phase which forms a surface of the polymer molding, to produce the conductive structures on the surface of the polymer molding, the thermal treatment comprising heating to a temperature which corresponds at least to the melting temperature of the at least one polymer phase.

Preference is given to a process according to point 1, characterized in that the polymer phase(s) is/are obtained by mixing molten polymer with 0.1-10% by weight of carbon nanotubes, based on the mass of the polymer phase(s).

2. Process according to point 1, characterized in that the polymer phase(s) is/are obtained by mixing molten polymer with 0.1-10% by weight of carbon nanotubes, based on the mass of the polymer phase(s).

3. Process according to point 1 or 2, characterized in that the polymer molding is obtained by melting at least one polymer phase which comprises carbon nanotubes (CNTs) in a proportion between 1 and 40% by weight with at least one further polymer phase with a lower carbon nanotube (CNT) content.

4. Process according to any of the preceding points, characterized in that the polymer phase which comprises carbon nanotubes (CNTs) in a proportion between 1 and 40% by weight comprises one or more polymer(s) selected from the group consisting of polycarbonate, polystyrene, acrylonitrile-butadiene-styrene (ABS), styrene-maleic anhydride (SMA), styrene-methyl methacrylate (SMMA), polymethyl methacrylate (PMMA), polybutylene terephthalate (PBT), polyethylene terephthalate (PET), nylon-6 (PA 6), nylon-6,6 (PA 66), nylon-6,4 (PA 64), nylon-12 (PA 12), aromatic polyamide and polysulfone.

5. Process according to any of the preceding points, characterized in that the thermal treatment of the surface(s) of the polymer molding is effected by contact with a heated body, gas or liquid, or by electromagnetic radiation.

6. Process according to any of the preceding points, characterized in that the electromagnetic radiation used is laser radiation or IR radiation.

7. Polymer molding comprising at least one polymer phase containing carbon nanotubes (CNTs), said polymer molding having electrically or thermally conductive structures on the surface, the concentration of the CNTs in the regions of the electrically conductive surface structures being higher than in the electrically nonconductive surface regions. The polymer molding preferably comprises at least one polymer phase containing carbon nanotubes (CNTs), said polymer molding having electrically or thermally conductive structures on the surface, the concentration of the CNTs in the regions of the electrically conductive surface structures being higher than in the electrically nonconductive surface regions, and said electrically nonconductive surface regions comprising CNTs. In this context, the expression “concentration of CNTs in the regions of the electrically conductive surface structures” “electrically nonconductive surface regions” encompasses examination of the outer surface layer for the CNT content down to a depth of 10 μm, preferably down to 1 μm.

8. Polymer molding according to point 7, characterized in that at least one polymer phase comprises a polymer selected from the group consisting of: polycarbonate, polystyrene, acrylonitrile-butadiene-styrene (ABS), styrene-maleic anhydride (SMA), styrene-methyl methacrylate (SMMA), polymethyl methacrylate (PMMA), polybutylene terephthalate (PBT), polyethylene terephthalate (PET), nylon-6 (PA 6), nylon-6,6 (PA 66), nylon-6,4 (PA 64), nylon-12 (PA 12), aromatic polyamide and polysulfone.

9. Polymer molding according to either of points 7 and 8, characterized in that between 0.01 and 10% by weight of CNTs is present, based on the total mass of the polymer phase(s) of the polymer molding.

10. Polymer molding according to any of points 7 to 9, characterized in that the polymer molding comprises at least two separate polymer phases.

11. Polymer molding according to any of points 7 to 10, characterized in that one of the polymer phases has a higher proportion of carbon nanotubes (CNTs) than the other phase(s).

12. Polymer molding according to any of the preceding points, wherein a polymer blend composed of polycarbonate with polyolefin, especially with polypropylene or polyethylene, is used for the polymer molding.

13. Process according to point 1, in which the polymer phase(s) is/are obtained by mixing molten polymer with 0.1-10% by weight of carbon nanotubes, based on the mass of the polymer phase(s).

14. Device for producing a structure on a body to be processed, characterized by an energy source with at least one electrode provided for release of energy with which the body to be processed can be at least partially heated. The device preferably serves for thermal treatment of the surface of polymer moldings, which gives rise to defined electrically conductive structures at the thermally treated sites.

15. Device according to point 14, characterized in that the body to be processed is a polymer molding composed of at least one polymer phase which comprises carbon nanotubes.

16. Device according to point 14 or 15, characterized in that the energy source is an electrical energy source.

17. Device according to point 16, characterized in that the energy source has at least two electrodes which can be placed onto the body to be processed, it being possible to use the two electrodes to pass a current through the body to be processed, which heats the body to be processed.

18. Device according to point 16 or 17, characterized in that the electrical energy source is a voltage source preferably with an open-circuit voltage greater than 500 V and especially with an open-circuit voltage of 1000 V.

19. Device according to any of the preceding points, characterized in that the structure to be produced is an electronic circuit.

20. Device according to any of the preceding points, characterized in that the first electrode and the second electrode are arranged in one plane or in two different planes of the body to be processed.

21. Device according to any of the preceding points, characterized in that the distance between the first and second electrodes is less than 1 mm.

22. Device according to any of the preceding points, characterized by a spacer which connects the first and second electrodes to one another.

23. Apparatus for producing a structure on a body to be processed, comprising the body to be processed and a device according to any of points 1-9, which at least partially heats the body to be processed.

24. Plotter comprising an apparatus according to any of the preceding points.

25. Matrix printer comprising an apparatus according to any of the preceding points as a print matrix.

26. Probe comprising an apparatus according to any of the preceding points as a probe tip.

27. Process for producing a structure on a body to be processed, characterized in that electrical energy is passed between two different points on the body to be processed.

28. Circuit board arrangement comprising at least one circuit board comprising at least one electrically conductive track and at least one electronic component, said circuit board comprising a polymer molding containing 0.1-10% by weight of carbon nanotubes (CNTs), based on the mass of the polymer phase(s), and said at least one electronic component being bonded to at least one electrically conductive track of said circuit board by an organic adhesive composition comprising 0.05-10% by weight of carbon nanotubes (CNTs), based on the mass of the adhesive composition, and/or by a bond which comprises material comprising carbon nanotubes (CNTs), especially one or more polymer phases comprising carbon nanotubes (CNTs), and/or by a solder bond.

29. Circuit board arrangement according to point 28, wherein the organic adhesive composition has a resistance of less than 100 ohms, especially less than 50 ohms.

30. Circuit board arrangement according to any of the preceding points, wherein the organic adhesive composition comprises at least one adhesive which is selected from the group consisting of: acrylate adhesives, phenol-formaldehyde resin adhesives, silicone adhesives and polyurethane adhesives, said adhesive composition preferably comprising a urethane acrylate adhesive.

31. Circuit board arrangement according to any of the preceding points, wherein the bond between the at least one electrically conductive track and the at least one electronic component is electrically conductive and has a resistance of less than 100 ohms.

32. Adhesive composition comprising 0.05-10% by weight of carbon nanotubes (CNTs).

33. Adhesive composition according to point 32, wherein the adhesive composition comprises at least one adhesive which is selected from the group consisting of: acrylate adhesives, phenol-formaldehyde resin adhesives, silicone adhesives and polyurethane adhesives, said adhesive composition preferably comprising a urethane acrylate adhesive.

34. Adhesive composition according to any of the preceding points, wherein the organic adhesive composition has a resistance of less than 100 ohms, especially less than 50 ohms.

35. Process for applying at least one electronic component to a circuit board, comprising the following steps:

a) providing a circuit board comprising at least one electrically conductive track or at least one electrically conductive region, said circuit board comprising a polymer molding containing 0.1-10% by weight of carbon nanotubes (CNTs), based on the mass of the polymer phase(s),
b) providing at least one electronic component, and
c) bonding, preferably thermally and/or electrically conductively bonding, the electronic component to the at least one electrically conductive track or the at least one electrically conductive region using the adhesive composition according to any of claims 5 to 7 and/or by establishing a bond which comprises material comprising carbon nanotubes (CNTs), especially one or more polymer phases comprising carbon nanotubes (CNTs), and/or by establishing a solder bond.

36. Process according to point 35, wherein the establishment of the bond according to step c) comprises

aa) supplying energy to at least one section, especially to a surface section, of the polymer molding or of the electrically conductive track or of the electrically conductive region, which at least partially melts said section,
bb) contacting a section of the electronic component with the at least partially molten section of the polymer molding or of the electrically conductive track or of the electrically conductive region,
cc) forming a bond, especially an electrically conductive bond, between the section of the electronic component and the at least one section of the polymer molding or of the electrically conductive track or of the electrically conductive region.

37. Process according to point 36, wherein the step of supplying energy to at least one section of the polymer molding or of the electrically conductive track or of the electrically conductive region comprises

i) heating a section of the electronic component which is in contact with the polymer molding or the electrically conductive track or the electrically conductive region, or is designed for contacting with the polymer molding or the electrically conductive track or the electrically conductive region, and is contacted therewith after heating, and/or
ii) heating a section of the polymer molding or of the electrically conductive track or of the electrically conductive region.

38. Process according to any of the preceding points, wherein the step of supplying energy according to point 36 or wherein the step of heating according to point 37 is effected using a laser.

39. Process according to any of the preceding points, wherein the bond comprises or consists of one or more polymer phases comprising carbon nanotubes (CNTs).

40. Process according to point 39, wherein the bond is produced such that the bond comprises at least one polymer phase comprising carbon nanotubes (CNTs), preferably preceding from a polymer material which, before the heating to produce the bond, has a content of 0.05-10% by weight of carbon nanotubes (CNTs), preferably of 0.1-10% by weight of carbon nanotubes (CNTs), more preferably of 0.2-10% by weight of carbon nanotubes (CNTs), based in each case on the mass of the polymer material.

41. Use of an adhesive composition according to any of the preceding points for electrically conductive bonding of an electronic component to another electrically conductive component or molding, especially to an electrically conductive track or an electrically conductive region on a conductor track.

42. Circuit board arrangement comprising at least one circuit board comprising at least one electrically conductive track, said circuit board comprising a polymer molding containing 0.1-10% by weight of carbon nanotubes (CNTs), based on the mass of the polymer phase(s), and the at least one electrically conductive track comprising a metal layer, preferably a copper layer.

43. Circuit board arrangement according to point 42, wherein at least one electronic component is bonded to at least one electrically conductive track of the circuit board by an organic adhesive composition according to any of claims 5-7 and/or by establishing a bond which comprises material comprising carbon nanotubes (CNTs), and/or by establishing a solder bond.

44. Process for producing a circuit board arrangement according to any of the preceding points, comprising the steps of:

a) providing a polymer molding composed of at least one polymer phase which comprises carbon nanotubes (CNTs);
b) thermally treating at least one surface of the polymer molding to produce the conductive structures on the surface of the polymer molding, the thermal treatment comprising heating to a temperature which corresponds at least to the melting temperature of the at least one polymer phase, and
c) electroplating the electrically conductive structures with a metal, preferably with copper.

45. Process for producing a circuit board arrangement according to point 44, wherein, in an additional step d), at least one electronic component is bonded, especially electrically and/or thermally conductively bonded, to at least one conductor track of the circuit board using an adhesive composition according to any of claims 5-7 and/or by establishing a bond which comprises material comprising carbon nanotubes (CNTs), and/or by establishing a solder bond.

46. Process according to any of the preceding points, in which electroplating in step c) is effected by bathless electroplating.

47. More particularly, the invention relates to a polymer molding produced using the process according to the invention.

48. Use of a device for production of conductive structures on the surface of a polymer molding which has at least one polymer phase which comprises carbon nanotubes (CNTs), in which the device has an energy source with at least one electrode provided for release of energy with which the body to be processed can be at least partially heated. According to the invention, the conductive structure is produced on the surface of the polymer phase which comprises CNTs, said polymer phase which comprises CNTs forming a surface of the polymer molding.

1. Process for producing conductive structures on a surface of a nonconductive or only low-conductivity polymer molding, comprising:
a) providing polymer molding comprising at least one polymer phase which comprises carbon nanotubes (CNTs);
b) thermally treating at least one surface of the polymer molding to produce the conductive structures on the surface of the polymer molding, wherein the thermal treatment comprises heating to a temperature which corresponds at least to the melting temperature of the at least one polymer phase.

2. Process according to claim 1, characterized in that the polymer phase is obtained by mixing molten polymer with 0.1-10% by weight of carbon nanotubes, based on the mass of the polymer phase.

3. Process according to claim 1, characterized in that the polymer molding is obtained by melting at least one polymer phase which comprises carbon nanotubes (CNTs) in a proportion between 1 and 40% by weight with at least one further polymer phase with a lower carbon nanotube (CNT) content.

4. Process according to claim 1, characterized in that the polymer phase comprises at least one polyolefin, or comprises at least one light-conducting additive or a heat-conducting additive with a conductivity of more than 20 W/mK or blowing agent.

5. Process according to claim 1, characterized in that the thermal treatment of the surface of the polymer molding is effected by a process selected from the group consisting of contact with a heated body, gas or liquid, and contact with electromagnetic radiation, including laser radiation or IR radiation.

6. Polymer molding with conductive structures on the surface comprising at least one polymer phase which comprises carbon nanotubes (CNTs) thermally treated to produce the conductive structures to a temperature of at least the melting point of the at least one polymer phase, wherein said polymer molding has electrically or thermally conductive structures on the surface, wherein the concentration of the CNTs in the electrically conductive surface structures is higher than in an electrically nonconductive surface region, and wherein said electrically nonconductive surface region comprises CNTs.

7. Polymer molding according to claim 6, wherein the polymer phase comprises a polymer blend comprised of polycarbonate with a polyolefin selected from the group consisting of polypropylene and polyethylene.

8. Circuit board arrangement comprising at least one circuit board, said circuit board a comprising the polymer molding according to claim 6 and further comprising at least one electrically conductive track, wherein said polymer molding comprises 0.1-10% by weight of carbon nanotubes (CNTs), based on the mass of the polymer phase(s), and
a) wherein said at least one electrically conductive track comprises a metal layer, preferably a copper layer, and
b) at least one electronic component, wherein said at least one electronic component is bonded to at least one electrically conductive track of said circuit board by material selected from the group consisting of an organic adhesive composition comprising 0.05-10% by weight of carbon nanotubes (CNTs), based on the mass of the adhesive composition, by a bond which comprises material comprising carbon nanotubes (CNTs), especially one or more polymer phases comprising carbon nanotubes (CNTs), and by a solder bond.

9. Circuit board arrangement according to claim 8, wherein the organic adhesive composition comprises at least one adhesive which is selected from the group consisting of: acrylate adhesives, phenol-formaldehyde resin adhesives, silicone adhesives and polyurethane adhesives.

10. Process for producing a circuit board arrangement, according to claim 8, comprising the steps of:
a) providing a polymer molding comprised of at least one polymer phase which comprises carbon nanotubes (CNTs);
b) thermally treating at least one surface of the polymer molding to produce the conductive structures on the surface of the polymer molding, wherein the thermal treatment comprises heating to a temperature which corresponds at least to the melting temperature of the at least one polymer phase, and
c) electroplating the electrically conductive structures with a metal, preferably with copper.

11. (canceled)

12. (canceled)

13. (canceled)

14. (canceled)

15. (canceled)

16. The process of claim 4, wherein the polyolefin comprises a cyclic polyolefin.

17. The circuit board arrangement of claim 9, wherein the adhesive comprises a urethane acrylate adhesive.

18. The process of claim 10 further comprising providing at least one electronic component.

19. The process of claim 10 further comprising providing at least one electronic component and thermally or electrically conductively bonding the electronic component to the at least one electrically conductive track or the at least one electrically conductive region by a process selected from the group consisting of applying an adhesive composition comprising 0.05-10% by weight of carbon nanotubes (CNTs), establishing a bond which comprises material comprising carbon nanotubes (CNTs), especially one or more polymer phases comprising carbon nanotubes (CNTs), and establishing a solder bond.

20. Process according to claim 1, characterized in that the polymer phase is obtained by mixing molten polymer with 0.05-10% by weight of carbon nanotubes, based on the mass of the polymer phase.

21. Process according to claim 19, wherein the bonding comprises
aa) supplying energy to at least one section, especially to a surface section of the polymer molding or of the electrically conductive track or of the electrically conductive region, which at least partially melts said section,
bb) contacting a section of the electronic component with the at least partially molten section of the polymer molding or of the electrically conductive track or of the electrically conductive region, and
cc) forming a bond, especially an electrically conductive bond, between the section of the electronic component and the at least one section of the polymer molding or of the electrically conductive track or of the electrically conductive region.

22. Process according to claim 21, wherein the step of supplying energy to at least one section of the polymer molding or of the electrically conductive track or of the electrically conductive region comprises
i) heating a section of the electronic component which is in contact with the polymer molding or the electrically conductive track or the electrically conductive region or is designed for contacting with the polymer molding or the electrically conductive track or the electrically conductive region, and is contacted therewith after heating, or
ii) heating a section of the polymer molding or of the electrically conductive track or of the electrically conductive region.

23. Process according to claim 21, wherein the step of supplying energy is effected using a laser.
